(19) United States
(12) Patent Application Publication
(10) Pub. No.: US 2008/0258131 A1
(43) Pub. Date: Oct. 23, 2008

(54) Light Emitting Diode

(75) Inventor: Kyoung Hoon Kim, Ansan-Si (KR)

Correspondence Address: MARGER JOHNSON & MCCOLLOM, P.C., 210 SW MORRISON STREET, SUITE 400, PORTLAND, OR, 97204, US

(73) Assignee: SEOUL OPTO-DEVICE CO., LTD., Ansan (KR)

(21) Appl. No.: 12/065,465

(22) PCT Filed: Sep. 29, 2006
(86) PCT No.: PCT/KR06/03917

§ 371 Date: Feb. 29, 2008

(30) Foreign Application Priority Data
Sep. 30, 2005 (KR) 10-2005-0091999
Oct. 7, 2005 (KR) 10-2005-0094430

(51) Int. Cl. H01L 33/00

(52) U.S. Cl. 257/13; 257/E33.008; 257/E33.027; 257/E33.028

(57) ABSTRACT

The present invention relates to a light emitting diode. More specifically, the present invention relates to a light emitting diode comprising an N-type semiconductor layer formed on a substrate, an active layer formed on the N-type semiconductor layer and a P-type semiconductor layer formed on the active layer, wherein the active layer is formed to have either a quantum well structure in which an AlₓGa₁₋ₓN (0≦x<1) well layer and an AlN barrier layer are alternately laminated or a quantum well structure in which a well layer and a barrier layer are formed of a compound semiconductor layer containing phosphorous (P) and are alternately laminated. Accordingly, far-ultraviolet light can be easily emitted and the optical power of the light emitting diode can also be improved.

### TECHNICAL FIELD

The present invention relates to a compound semiconductor light emitting diode, and more particularly, to a compound semiconductor light emitting diode which comprises either an active layer having a quantum well structure consisting of an AlₓGa₁₋ₓN well layer and an AlN barrier layer or an active layer having a quantum well structure consisting of an AlNP well layer and an AlNP barrier layer such that far-ultraviolet light can be easily emitted and the optical power thereof can be improved.

### BACKGROUND ART

A light emitting diode is basically a semiconductor PN junction diode. When joining P-type and N-type semiconductors with each other and then applying voltage to the joined P-type and N-type semiconductors, holes of the P-type semiconductor move toward the N-type semiconductor and gather in a middle layer whereas electrons of the N-type semiconductor move toward the P-type semiconductor and gather in a middle layer that is a lowermost portion of a conduction band. These electrons are dropped into holes of a valence band and emit energy as much as a height difference between the conduction band and the valance band, i.e. an energy gap, wherein the energy is emitted in the form of light.

Generally, a light emitting diode has a structure in which a substrate, a buffer layer, an N-type semiconductor layer, an active layer and a P-type semiconductor layer are laminated. Furthermore, a P-type electrode is formed on the P-type semiconductor layer, a predetermined region of the N-type semiconductor layer is exposed, and an N-type electrode is formed on the exposed region of the N-type semiconductor layer.

On the other hand, the active layer is formed to have a quantum well structure in which a well layer with a small energy band gap and a barrier layer with a relatively larger energy band gap than the well are alternately laminated once or several times.

InₓGa₁₋ₓN is mainly used as a material of the active layer, wherein an emission wavelength can vary according to the change in the composition of Indium (In). That is, the emission wavelength is shifted toward a long wavelength as the composition of In increases, whereas the emission wavelength is shifted toward a short wavelength as the composition of In decreases. Therefore, when x=0 (i.e., the active layer is GaN), the active layer emits light with an emission wavelength of 363 nm. Alternatively, when x=1 (i.e., the active layer is InN), the active layer emits light with an emission wavelength of 650 nm/1,550 nm at 0.8 eV/1.9 eV. However, according to the InₓGa₁₋ₓN, it is difficult to emit far-ultraviolet light of 300 nm or less from the active layer.

### DISCLOSURE OF INVENTION

### Technical Problem

Therefore, an object of the present invention is to provide a light emitting diode having a quantum well structure wherein AlN is used as a barrier layer to improve the characteristics of an active layer of the quantum well structure such that far-ultraviolet light can be easily emitted and the optical power thereof can be improved.

Another object of the present invention is to provide a light emitting diode having a quantum well structure wherein an active layer with a quantum well structure comprised of an AlNP well layer and an AlNP barrier layer is used such that far-ultraviolet light can be easily emitted and the optical power thereof can be improved.

### Technical Solution

According to an aspect of the present invention, there is provided a light emitting diode, comprising an N-type semiconductor layer formed on a substrate, an active layer formed on the N-type semiconductor layer, and a P-type semiconductor layer formed on the active layer, wherein the active layer is formed to have a quantum well structure in which an AlₓGa₁₋ₓN (0≦x≦1) well layer and an AlN barrier layer are alternately laminated.

Preferably, each of the well layer and the barrier layer is formed to a thickness of 5 to 1,000 Å.

Preferably, the AlₓGa₁₋ₓN well layer and the AlN barrier layer are alternately laminated two to one thousand times.

The AlₓGa₁₋ₓN well layer may be formed at a growth rate of 0.01 to 10 m/hour using a gallium source, an aluminum source and a nitrogen source at a temperature of 900 to 1,300° C. and a pressure of 30 to 760 torr.

Preferably, the AlₓGa₁₋ₓN well layer has a mole ratio of aluminum and gallium to nitrogen of 1:50 to 1:50,000.

The AlN barrier layer may be formed at a growth rate of 0.01 to 10 m/hour using an aluminum source and a nitrogen source at a temperature of 900 to 1,300° C. and a pressure of 30 to 760 torr.

Preferably, the AlN barrier layer has a mole ration of aluminum to nitrogen of 1:50 to 1:50,000.

The light emitting diode may further comprise a buffer layer formed between the substrate and the N-type semiconductor layer.

The light emitting diode may further comprise an N-type clad layer formed between the N-type semiconductor layer and the active layer, and a P-type clad layer formed between the P-type semiconductor layer and the active layer.

According to another aspect of the present invention, there is provided a light emitting diode, comprising an N-type semiconductor layer formed on a substrate, an active layer formed on the N-type semiconductor layer, and a P-type semiconductor layer formed on the active layer, wherein the active layer is formed to have a quantum well structure in which a well layer and a barrier layer are formed of a compound semiconductor layer containing phosphorous (P) and are alternately laminated.

Preferably, each of the well layer and the barrier layer is formed to a thickness of 5 to 1,000 Å.

Preferably, the well and the barrier are alternately laminated two to one thousand times.

Preferably, the well layer is formed of AlNₓP₁₋ₓ and the barrier layer is formed of AlN_{y}P_{1-y}, wherein 0<x, y<1, and y>x.

The well layer and the barrier layer may be formed at a growth rate of 0.01 to 10 m/hour using an aluminum source, a nitrogen source and a phosphorous source at a temperature of 400 to 1,200° C. and a pressure of 20 to 760 torr.

Preferably, each of the well layer and the barrier layer has a mole ration of aluminum to nitrogen and phosphorous of 1:50 to 1:50,000.

The light emitting diode may further comprise a buffer layer formed between the substrate and the N-type semiconductor layer.

The light emitting diode may further comprise an N-type clad layer formed between the N-type semiconductor layer and the active layer, and a P-type clad layer formed between the P-type semiconductor layer and the active layer.

### ADVANTAGEOUS EFFECTS

As described above, in the present invention, an active layer having a quantum well structure is formed using AlGaN well layers and AlN barrier layers such that the characteristics of the active layer can be improved. Therefore, far-ultraviolet light with an emission wavelength of 200 nm to 300 nm can be easily emitted and the optical power of a light emitting diode can also be improved.

Further, since an active having a quantum well structure is formed using AlNP well layers and AlNP barrier layers that can be grown more easily than AlGaN layers, far-ultraviolet light with an emission wavelength of 200 nm to 300 nm can be easily emitted and the optical power of a light emitting diode can also be improved.

### BRIEF DESCRIPTION OF THE DRAWINGS

FIG. 1 is a sectional view illustrating an active layer having a quantum well structure according to an embodiment of the present invention.

FIG. 2 is a sectional view illustrating an active layer having a quantum well structure according to another embodiment of the present invention.

FIG. 3 is an energy diagram of the active layer having a quantum well structure according to the present invention.

FIG. 4 is a sectional view illustrating a first embodiment of a compound semiconductor light emitting diode comprising an active layer having a quantum well structure according to the present invention.

FIG. 5 is a sectional view illustrating a second embodiment of a compound semiconductor light emitting diode comprising an active layer having a quantum well structure according to the present invention.

### BEST MODE FOR CARRYING OUT THE INVENTION

Hereinafter, preferred embodiments of the present invention will be described in detail with reference to the accompanying drawings.

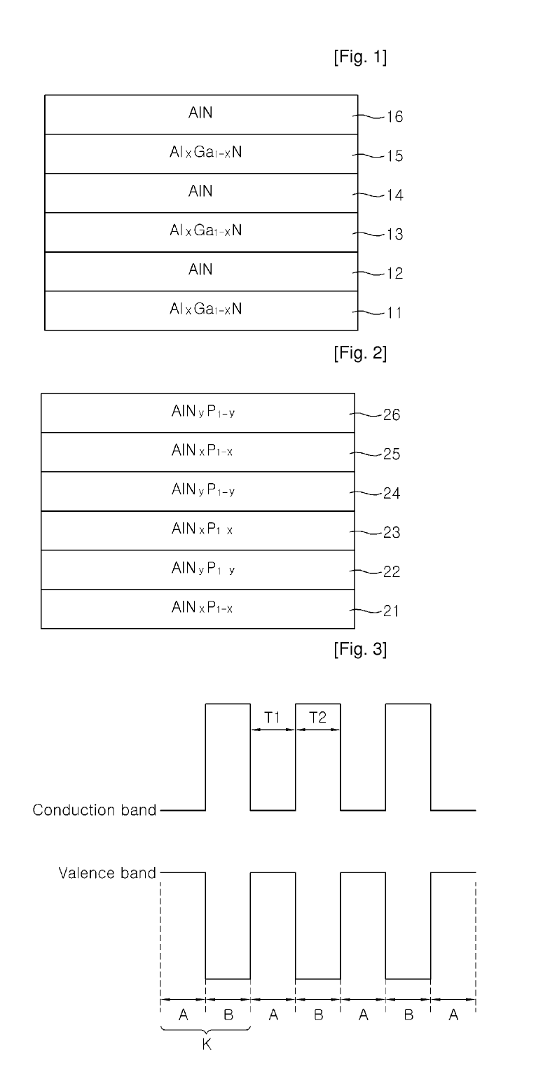

FIG. 1 is a sectional view illustrating an active layer having a quantum well structure according to an embodiment of the present invention, and FIG. 3 is an energy diagram of an active layer.

Referring to FIG. 1, an active layer according to an embodiment of the present invention comprises AlₓGa₁₋ₓN (0≦x≦1) well layers 11, 13 and 15 and AlN barrier layers 12, 14 and 16, wherein a plurality of well layers and a plurality of barrier layers are alternately laminated at least once. In such a quantum well structure, a barrier layer B has high conduction band energy and low valence band energy whereas a well layer A has low conduction band energy and high valence band energy, as illustrated in an energy diagram of FIG. 3. Therefore, the barrier layer B has an energy band gap greater than the well layer A.

In order to form an active layer, it is preferable to alternately grow an AlₓGa₁₋ₓN (0≦x≦1) well layer 11, 13 or 15 with a thickness of 5 to 1,000 and an AlN barrier layer 12, 14 or 16 with a thickness of 5 to 1,000 such that the active layer is formed to have 2 to 1,000 layers. It is preferred that a well layer 11, 13 or 15 and a barrier layer 12, 14 or 16, which have a quantum well structure according to one embodiment of the present invention, are formed respectively within the aforementioned thickness range, wherein the well layer 11, 13 or 15 and the barrier layer 12, 14 or 16 may be the same as or different from each other in view of their thickness.

In order to form the active layer having the quantum well structure, an AlₓGa₁₋ₓN (0≦x≦1) well layer is grown at a growth rate of 0.01 to 10 m/hour by introducing a gallium (Ga) source, an aluminum (Al) source and a nitrogen (N) source into a reactor at a temperature of 900 to 1,300° C. and a pressure of 30 to 760 torr. Here, trimethylgallium (TMGa) or triethylgallium (TEGa) may be used as a gallium (Ga) source, trimethylaluminum (TMAl) or triethylaluminum (TEAl) may be used as an aluminum (Al) source, and NH₃ may be used as a nitrogen (N) source. Furthermore, a gallium and aluminum to nitrogen ratio (a III:V ratio) is preferably 1:50 to 1:50,000, wherein the III:V ratio refers to a mole ratio in a reactor. That is, the III:V ratio is a ratio of Ga and/or Al to N contained in NH₃. In other words, the III:V ratio refers to a mole concentration ratio of Ga and Al to N.

Then, an AlN barrier layer is grown at a growth rate of 0.01 to 10 m/hour by introducing an aluminum source and a nitrogen source into a reactor at a temperature of 900 to 1,300° C. and a pressure of 30 to 760 torr. That is, an AlN film is formed by stopping the introduction of the gallium source into the reactor at the same temperature and pressure in a state where the aluminum source and the nitrogen source still flow into the reactor. Here, trimethylaluminum (TMAl) or triethylaluminum (TEAl) is used as an aluminum source, and NH₃ is used as a nitrogen source. Furthermore, the AlN barrier layer is formed in a state where a III:V ratio of Al to N is maintained within a range of 1:50 to 1:50,000.

A process of introducing a gallium source again into the reactor to form an AlₓGa₁₋ₓN (0≦x≦1) well layer and stopping the introduction of the gallium source into the reactor to form an AlN barrier layer is repeated until an active layer with a desired thickness is obtained. Furthermore, the AlN barrier layer and the AlₓGa₁₋ₓN (0≦x≦1) well layer can be doped with silicon (Si) or magnesium (Mg), if necessary.

Here, an Al content in and thickness of the well layer in the active layer having a quantum well structure can be changed to obtain a target wavelength. Namely, a band gap increases to emit short-wavelength light when the Al content in the well layer increases, whereas long-wavelength light is emitted when the thickness of the well layer increases.

As described above, using a barrier layer made of AlN in a quantum well structure improves the film quality and is more effective in the blocking of electrons as compared with using a conventional barrier layer made of AlGaN.

In addition, a light emitting diode having the aforementioned structure may be used as a light receiving element that generates electric energy (current) according to external optical energy. When reverse voltage is applied to a normal diode, current hardly flows through the diode. However, if optical energy is applied to an active layer having a quantum well structure according to an embodiment of the present invention, current flows through the active layer by means of the optical energy according to a principle opposite to the operating principle of the aforementioned light emitting diode. That is, when optical energy higher than band gap energy is applied to electrons in an active layer of the foregoing diode, the electrons move to allow current to flow through the active layer. At this time, the flow of current is proportional to the intensity of light applied to the electrons. In the meantime, in order to use the element having the aforementioned structure as a light receiving element, the element can further include a light-focusing unit for focusing optical energy.

FIG. 2 is a sectional view of an active layer having a quantum well structure according to another embodiment of the present invention, and FIG. 3 is an energy diagram of an active layer.

Referring to FIG. 2, an active layer according to another embodiment of the present invention comprises AlN P well layers 21, 23 and 25 and AlN P barrier layers 22, 24 and 26 and is formed in such a manner that a plurality of well layers and barrier layers are alternately laminated at least once, wherein 0<x, y<1, and y>x. As described above, when an active layer having a quantum well structure comprising AlNP-based well layers and barrier layers is formed, the active layer emits far-ultraviolet light with a wavelength of about 200 nm to 300 nm. In such a quantum well structure, a barrier layer B has high conduction band energy and low valence band energy, while a well layer A has low conduction band energy and high valence band energy, as illustrated in an energy diagram of FIG. 3. Therefore, the barrier layer B has an energy band gap greater than the well layer A.

In order to form the active layer, it is preferable to alternately grow an AlNₓP₁₋ₓ well layer 21, 23 or 25 with a thickness of 5 to 1,000 and an AlN_{y}P_{1-y} barrier layer 22, 24 or 26 with a thickness of 5 to 1,000 such that the active layer is formed to have 2 to 1,000 layers. It is preferred that a well layer 21, 23 or 25 and a barrier layer 22, 24 or 26, which have a quantum well structure according to another embodiment of the present invention, are formed respectively within the aforementioned thickness range, wherein the well layer 21, 23 or 25 and the barrier layer 22, 24 or 26 may be the same as or different from each other in view of their thickness.

In order to form an active layer having a quantum well structure, an AlNₓP₁₋ₓ well layer 21, 23 or 25 and an AlN_{y}P_{1-y} barrier layer 22, 24 or 26 are grown at a growth rate of 0.01 to 10 m/hour by introducing an aluminum (Al) source, a nitrogen (N) source and a phosphorous (P) source into a reactor at a temperature of 400 to 1,200° C. and a pressure of 20 to 760 torr. At this time, the AlNₓP₁₋ₓ well layer 21, 23 or 25 and the AlN_{y}P_{1-y} barrier layer 22, 24 or 26 are grown by controlling the introduced amounts of nitrogen (N) and phosphorous (P) in a state where an introduced amount of aluminum (Al) remains unchanged. Namely, the AlNₓP₁₋ₓ well layer 21, 23 or 25 is formed when the introduced amounts of nitrogen (N) and phosphorous (P) are decreased, whereas the AlN_{y}P_{1-y} barrier layer 22, 24 or 26 is formed when the introduced amounts of nitrogen (N) and phosphorous (P) are increased. Here, a content ratio of aluminum (Al) to nitrogen (N) and phosphorous (P) is preferably adjusted to about 1:50 to 1:50,000.

An active layer having a quantum well structure configured by alternately laminating well layers and barrier layers made of AlNP as described above emits far-ultraviolet light with a wavelength of 200 nm to 300 nm. Furthermore, the active layer according to the present invention can be grown more easily as compared with a conventional active layer.

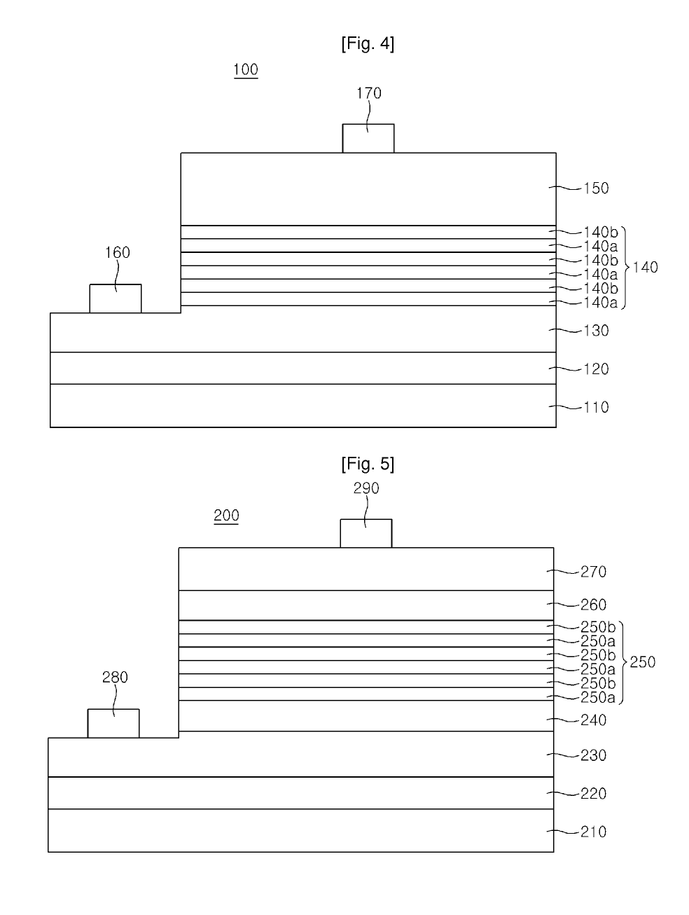

FIG. 4 is a sectional view illustrating a first embodiment of a compound semiconductor light emitting diode 100 comprising an active layer having a quantum well structure according to the present invention.

Referring to FIG. 4, a compound semiconductor light emitting diode 100 comprising an active layer having a quantum well structure according to the present invention comprises a substrate 110, a buffer layer 120, an N-type semiconductor layer 130, an active layer 140 having a quantum well structure and a P-type semiconductor layer 150, which are sequentially laminated on the substrate 110. The compound semiconductor light emitting diode may further comprise an N-type electrode 160 formed on the N-type semiconductor layer 130 and a P-type electrode 170 formed on the P-type semiconductor layer 150.

The substrate 110 may be made of a variety of materials such as silicon (Si), silicon carbide (SiC), sapphire and the like.

The buffer layer 120, the N-type semiconductor layer 130, the active layer 140 having a quantum well structure and the P-type semiconductor layer 150 are sequentially formed on the substrate 110. At this time, the buffer layer 120 can be made of various materials such as GaN, AlN, GaInN, AlGaInN, SiN and the like, and the semiconductor layer can be made of nitride-based compounds with various compositions including GaN.

Furthermore, Si, Ge, Sn, Te, S and the like can be used as an N-type dopant, and Zn, Cd, Be, Mg, Ca, Sr, Ba and the like can be used as a P-type dopant. However, the present invention is not limited thereto.

A predetermined region on the N-type semiconductor layer 130 is exposed through an etching process, and an N-type electrode 160 is formed on the exposed region of the N-type semiconductor layer 130. Furthermore, a P-type electrode 170 is formed on the P-type semiconductor layer 150.

In the meantime, the active layer 140 is formed to have a quantum well structure in which well layers 140a and barrier layers 140b are alternately laminated. The active layer 140 is formed of either a laminate of AlₓGa₁₋ₓN well layers and AlN barrier layers according to one embodiment of the present invention, or a laminate of AlNₓP₁₋ₓ well layers and AlN_{y}P_{1-y} barrier layers according to another embodiment of the present invention. Furthermore, the active layer 140 may has a single quantum well structure or a multiple quantum well structure comprised of a plurality of other pairs of well layers and barrier layers.

FIG. 5 is a sectional view illustrating a second embodiment of a compound semiconductor light emitting diode 200 comprising an active layer having a quantum well structure according to the present invention. When comparing the first and second embodiments with each other, the second embodiment of a compound semiconductor light emitting diode has a constitution similar to the first embodiment, except that N-type and P-type clad layers are additionally formed.

Referring to FIG. 5, the compound semiconductor light emitting diode 200 comprises a substrate 210, a buffer layer 220, an N-type semiconductor layer 230, an N-type clad layer 240, an active layer 250 having a quantum well structure, a P-type clad layer 260 and a P-type semiconductor layer 270, which are sequentially laminated on the substrate 210. The compound semiconductor light emitting diode may further comprise an N-type electrode 280 formed on the N-type semiconductor layer 230 and a P-type electrode 290 formed on the P-type semiconductor layer 270.

The N-type and P-type clad layers 240 and 260 efficiently confines electrons and holes within the active layer 250 having a quantum well structure to perform a function of improving efficiency of recombining the electrons and holes.

The aforementioned descriptions are merely for illustration of a PCB for a compound semiconductor light emitting diode according to the present invention. Thus, the present invention is not limited to the aforementioned embodiments and it will be readily understood by those skilled in the art that various modifications and changes can be made thereto within the technical spirit and scope of the present invention. It is also apparent that the modifications and changes fall within the scope of the present invention defined by the appended claims.

1. A light emitting diode, comprising:
an N-type semiconductor layer formed on a substrate;
an active layer formed on the N-type semiconductor layer; and
a P-type semiconductor layer formed on the active layer,
wherein the active layer is formed to have a quantum well structure in which an AlₓGa₁₋ₓN (0≦x≦1) well layer and an AlN barrier layer are alternately laminated.

2. A light emitting diode, comprising:
an N-type semiconductor layer formed on a substrate;
an active layer formed on the N-type semiconductor layer; and
a P-type semiconductor layer formed on the active layer,
wherein the active layer is formed to have a quantum well structure in which a well layer and a barrier layer are formed of a compound semiconductor layer containing phosphorous (P) and are alternately laminated.

3. The light emitting diode as claimed in claim 1, wherein each of the well layer and the barrier layer is formed to a thickness of 5 to 1,000 Å.

4. The light emitting diode as claimed in claim 1, wherein the AlₓGa₁₋ₓN well layer is formed at a growth rate of 0.01 to 10 μm/hour using a gallium source, an aluminum source and a nitrogen source at a temperature of 900 to 1,300° C. and a pressure of 30 to 760 torr.

5. The light emitting diode as claimed in claim 4, wherein the AlₓGa₁₋ₓN well layer has a mole ratio of aluminum and gallium to nitrogen of 1:50 to 1:50,000.

6. The light emitting diode as claimed in claim 1, wherein the AlN barrier layer is formed at a growth rate of 0.01 to 10 μm/hour using an aluminum source and a nitrogen source at a temperature of 900 to 1,300° C. and a pressure of 30 to 760 torr.

7. The light emitting diode as claimed in claim 6, wherein the AlN barrier layer has a mole ration of aluminum to nitrogen of 1:50 to 1:50,000.

8. The light emitting diode as claimed in claim 2, wherein the well layer is formed of AlNₓP₁₋ₓ and the barrier layer is formed of AlN_{y}P_{1-y}, wherein 0<x, y<1, and y>x.

9. The light emitting diode as claimed in claim 8, wherein the well layer and the barrier layer are formed at a growth rate of 0.01 to 10 μm/hour using an aluminum source, a nitrogen source and a phosphorous source at a temperature of 400 to 1,200° C. and a pressure of 20 to 760 torr.

10. The light emitting diode as claimed in claim 9, wherein each of the well layer and the barrier layer has a mole ration of aluminum to nitrogen and phosphorous of 1:50 to 1:50,000.

11. The light emitting diode as claimed in claim 1, wherein the AlₓGa₁₋ₓN well layer and the AlN barrier layer are alternately laminated two to one thousand times.

12. The light emitting diode as claimed in claim 2, wherein the well layer and the barrier layer are alternately laminated two to one thousand times.

13. The light emitting diode as claimed in claim 1 or 2, further comprising a buffer layer formed between the substrate and the N-type semiconductor layer.

14. The light emitting diode as claimed in claim 1 or 2, further comprising an N-type clad layer formed between the N-type semiconductor layer and the active layer, and a P-type clad layer formed between the P-type semiconductor layer and the active layer.
